(19) United States
(12) Patent Application Publication
(10) Pub. No.: US 2008/0185667 A1
(43) Pub. Date: Aug. 7, 2008

(54) Thin Film Semiconductor Device and Method for Manufacturing the Same

(76) Inventors: Kenichi Yoshino, Yokohama (JP); Akito Hara, Miyagi (JP); Michiko Takei, Nara (JP); Takuya Hirano, Tottori (JP)

Correspondence Address: NIXON & VANDERHYE, PC, 901 NORTH GLEBE ROAD, 11TH FLOOR, ARLINGTON, VA, 22203, US

(21) Appl. No.: 11/663,057

(22) PCT Filed: Sep. 17, 2004
(86) PCT No.: PCT/JP2004/013676

§ 371 Date: Oct. 30, 2007

(51) Int. Cl. H01L 29/786; H01L 21/28

(52) U.S. Cl. 257/412; 257/64; 438/479; 257/E29.293; 257/E29.158; 257/E21.202

(57) ABSTRACT

An Mo film (6) is formed on a SiO₂ film (5) by particularly using the film thickness and the deposition temperature (ambient temperature in a sputtering chamber) as the primary parameters and adjusting the film thickness to be within the range from 100 nm to 500 nm (more preferably 100 nm to 300 nm) and the deposition temperature to be within the range from 25° C. to 300° C., so as to control residual stress to have a predetermined value of 300 MPa or greater and to be oriented to increase the in-plane lattice constant. There can be thus provided a reliable CMOSTFT in which desired strain is easily and reliably imparted to polysilicon thin films (4a and 4b) to improve the mobility therein without adding an extra step of imparting the strain to the silicon thin film.

### TECHNICAL FIELD

The present invention relates to a thin film semiconductor device and a method for manufacturing the same, and particularly to a technology suitably applicable to a thin film transistor (TFT) used for a data driver, a gate driver, a pixel switching element and the like of an active matrix liquid crystal display and an EL panel display.

### BACKGROUND ART

In recent years, there is an increasing need for highly enhanced performance of semiconductor devices. In thin film transistors (TFTs), higher mobility is required to achieve, for example, a sheet computer. To achieve such high mobility, there have been on-going efforts, such as increasing the crystal grain size of a polysilicon thin film, improving crystallization, improving device structures and the like. To improve device structures, it is considered effective to impart strain to a polysilicon thin film where a channel region is formed, and there have been already proposed, for example, a method for forming a side wall that induces stress in a polysilicon thin film (see Patent Document 1) and a method for depositing a stressed film on a gate electrode (see Patent Document 2).

However, in the methods disclosed in Patent Documents 1 and 2, a typical TFT manufacturing process requires an extra step for forming a structure that imparts strain to the polysilicon thin film, so that the manufacturing process will be cumbersome and complicated, disadvantageously resulting in increased cost.

Patent Document 1: Japanese Patent Application Laid-Open No. 2003-203925

Patent Document 2: Japanese Patent Application Laid-Open No. 2001-60691

### SUMMARY OF THE INVENTION

The present invention has been made in view of the above problem and aims to provide a reliable thin film semiconductor device and a method for manufacturing the same in which desired strain is easily and reliably imparted to a semiconductor thin film so as to achieve improved mobility without adding any extra step of imparting the strain to the semiconductor thin film.

The thin film semiconductor device of the present invention includes an insulating substrate, a semiconductor thin film patterned on the insulating substrate and a gate electrode patterned on the semiconductor thin film via a gate insulating film. The gate electrode has a film thickness ranging from 100 nm to 500 nm and has residual stress of 300 MPa or greater that is oriented to increase the in-plane lattice constant. The residual stress in the gate electrode induces tensile stress in the semiconductor thin film, and the in-plane lattice constant therein becomes larger than that will be achieved when the tensile stress is not applied.

The film thickness of the gate electrode preferably ranges from 100 nm to 300 nm.

The method for manufacturing a thin film semiconductor device of the present invention includes the steps of pattering a semiconductor thin film on an insulating substrate and patterning a gate electrode on the semiconductor thin film via a gate insulating film. The gate electrode is formed such that the film thickness thereof is adjusted to be a value ranging from 100 nm to 500 nm so as to create residual stress of 300 MPa or greater oriented to increase the in-plane lattice constant. The residual stress induces tensile stress in the semiconductor thin film, so that the in-plane lattice constant therein is controlled to be larger than that will be achieved when the tensile stress is not applied.

The gate electrode is preferably formed such that the film thickness thereof is adjusted to be a value ranging from 100 nm to 300 nm so as to create residual stress in the gate electrode of 300 MPa or greater oriented to increase the in-plane lattice constant.

Furthermore, it is preferable to adjust the film thickness of the gate electrode to be a value ranging from 100 nm to 300 nm and the ambient temperature during the deposition to be a value ranging from 25° C. to 300° C., so as to create residual stress in the gate electrode of 300 MPa or greater oriented to increase the in-plane lattice constant.

### BRIEF DESCRIPTION OF THE DRAWINGS

FIG. 1 is a characteristic curve showing the result of measurement conducted to investigate the relationship between the film thickness (nm) of a deposited Mo film and residual stress (MPa);

FIG. 2 is a characteristic curve showing the result of measurement conducted, upon formation of a gate electrode made of Mo on a polysilicon thin film, to investigate the relationship between the film thickness (nm) of the gate electrode formed of a Mo film and Raman peaks (/cm);

FIG. 3 are characteristic curves showing the result of measurement conducted to investigate the relationship between the film thickness (nm) of a Mo film deposited at a number of deposition temperatures and residual stress (MPa);

FIG. 4A is a characteristic curve showing the result of measurement conducted to investigate the relationship between the film thickness (nm) of a gate electrode made of Mo and mobility (cm²/V×s) in an n-channel TFT;

FIG. 4B is a characteristic curve showing the result of measurement conducted to investigate the relationship between the film thickness (nm) of a gate electrode made of Mo and mobility (cm²/V×s) in a p-channel TFT;

FIG. 5A is a schematic cross-sectional view showing a method for manufacturing the CMOSTFT according to the first embodiment in the order of steps;

FIG. 5B is a schematic cross-sectional view showing a method for manufacturing the CMOSTFT according to the first embodiment in the order of steps;

FIG. 5C is a schematic cross-sectional view showing a method for manufacturing the CMOSTFT according to the first embodiment in the order of steps;

FIG. 5D is a schematic cross-sectional view showing a method for manufacturing the CMOSTFT according to the first embodiment in the order of steps;

FIG. 5E is a schematic cross-sectional view showing a method for manufacturing the CMOSTFT according to the first embodiment in the order of steps;

FIG. 5F is a schematic cross-sectional view showing a method for manufacturing the CMOSTFT according to the first embodiment in the order of steps;

FIG. 6A is a schematic cross-sectional view showing a method for manufacturing the CMOSTFT according to the second embodiment in the order of steps;

FIG. 6B is a schematic cross-sectional view showing a method for manufacturing the CMOSTFT according to the second embodiment in the order of steps;

FIG. 6C is a schematic cross-sectional view showing a method for manufacturing the CMOSTFT according to the second embodiment in the order of steps;

FIG. 6D is a schematic cross-sectional view showing a method for manufacturing the CMOSTFT according to the second embodiment in the order of steps;

FIG. 6E is a schematic cross-sectional view showing a method for manufacturing the CMOSTFT according to the second embodiment in the order of steps;

FIG. 6F is a schematic cross-sectional view showing a method for manufacturing the CMOSTFT according to the second embodiment in the order of steps;

FIG. 6G is a schematic cross-sectional view showing a method for manufacturing the CMOSTFT according to the second embodiment in the order of steps;

FIG. 6H is a schematic cross-sectional view showing a method for manufacturing the CMOSTFT according to the second embodiment in the order of steps;

FIG. 6I is a schematic cross-sectional view showing a method for manufacturing the CMOSTFT according to the second embodiment in the order of steps;

FIG. 7A is a schematic cross-sectional view showing the primary step of an example of the variation of a method for manufacturing the CMOSTFT according to the second embodiment;

FIG. 7B is a schematic cross-sectional view showing the primary step of an example of the variation of a method for manufacturing the CMOSTFT according to the second embodiment;

FIG. 8A is a schematic cross-sectional view showing a method for manufacturing the CMOSTFT according to the third embodiment in the order of steps;

FIG. 8B is a schematic cross-sectional view showing a method for manufacturing the CMOSTFT according to the third embodiment in the order of steps;

FIG. 8C is a schematic cross-sectional view showing a method for manufacturing the CMOSTFT according to the third embodiment in the order of steps;

FIG. 8D is a schematic cross-sectional view showing a method for manufacturing the CMOSTFT according to the third embodiment in the order of steps;

FIG. 8E is a schematic cross-sectional view showing a method for manufacturing the CMOSTFT according to the third embodiment in the order of steps;

FIG. 8F is a schematic cross-sectional view showing a method for manufacturing the CMOSTFT according to the third embodiment in the order of steps;

FIG. 8G is a schematic cross-sectional view showing a method for manufacturing the CMOSTFT according to the third embodiment in the order of steps;

FIG. 8H is a schematic cross-sectional view showing a method for manufacturing the CMOSTFT according to the third embodiment in the order of steps;

FIG. 8I is a schematic cross-sectional view showing a method for manufacturing the CMOSTFT according to the third embodiment in the order of steps;

FIG. 9A is a schematic cross-sectional view showing the primary step of an example of the variation of a method for manufacturing the CMOSTFT according to the third embodiment; and

FIG. 9B is a schematic cross-sectional view showing the primary step of an example of the variation of a method for manufacturing the CMOSTFT according to the third embodiment.

### DETAILED DESCRIPTION OF THE PREFERRED EMBODIMENTS

### Essential Features of the Present Invention

In manufacturing a TFT, the present inventor has come to the conclusion that without adding any extra step of imparting strain to a semiconductor thin film, such as a polysilicon thin film (strain that increases the in-plane lattice constant of the polysilicon thin film), residual stress in a gate electrode (residual stress oriented to increase the in-plane lattice constant) obtained by only a gate electrode formation step, that is, by only forming the gate electrode, is used to impart the strain to the polysilicon thin film. The present inventor has then conducted extensive investigation on specific approaches to realize the above findings.

It is generally known that a refractory metal film has high residual stress although the strength thereof slightly differs from each other depending on the deposition condition, and the strength of the residual stress increases as the film thickness decreases. The present inventor has focused on this knowledge and investigated the quantitative relationship between the film thickness and the tensile stress induced in a polysilicon thin film by using refractory metals, such as Mo, W, Ti, Nb, Re and Ru, as the gate electrode material and using the film thickness as the primary parameter with the other deposition conditions (including the deposition temperature, which will be described later) having the same values.

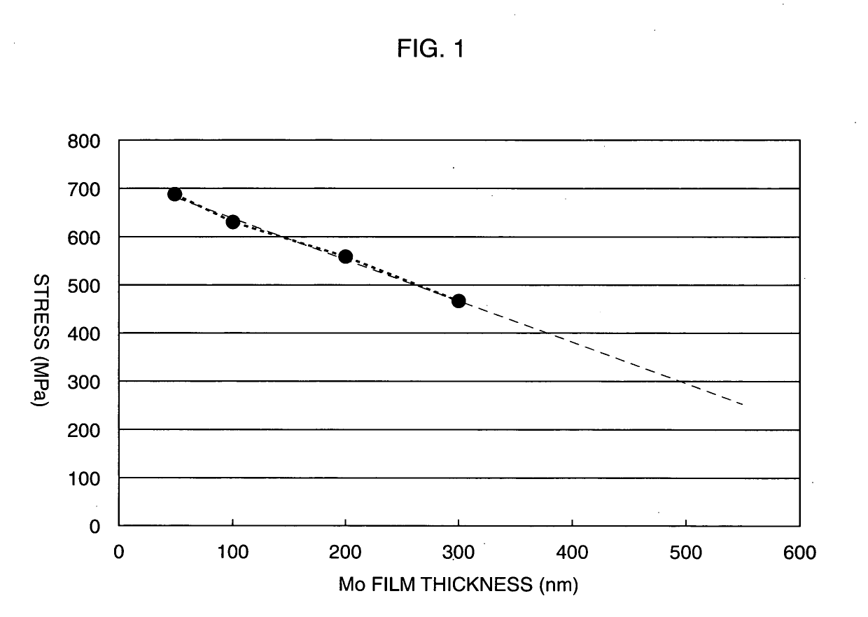

In this study, Mo was used as the refractory metal by way of example to investigate the relationship between the film thickness (nm) of the deposited Mo film and the residual stress (MPa). FIG. 1 shows the measurement results. It is seen from the figure that the residual stress is substantially proportional to the film thickness of the Mo film, more specifically, the former proportionally decreases as the latter increases.

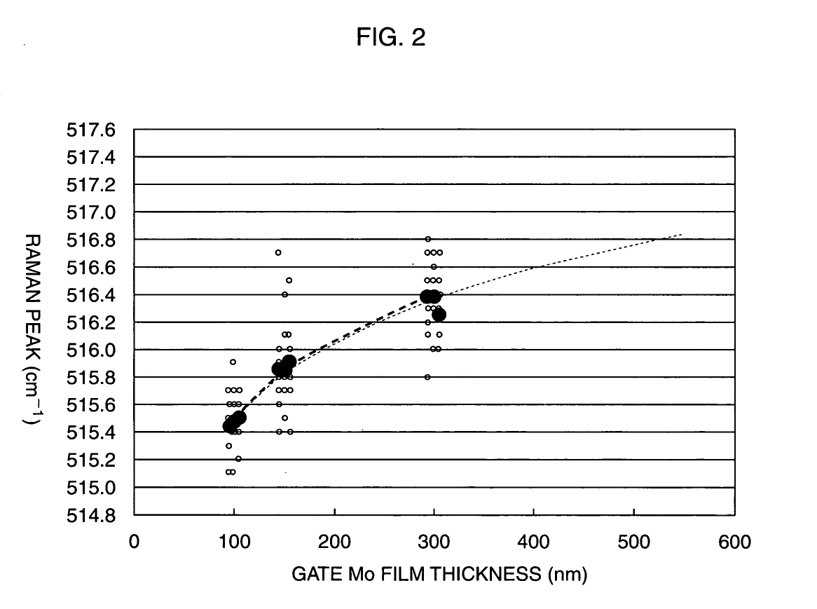

On the other hand, as an approach for measuring the amount of strain in a polysilicon thin film on which a gate electrode is formed, considering that in a TFT, a polysilicon thin film is formed on a transparent insulating substrate, such as a glass substrate, Raman spectroscopy capable of carrying out measurement from the back side of the substrate was employed. After the polysilicon thin film was formed on the glass substrate and the gate electrode made of Mo was patterned on the polysilicon thin film via a gate insulating film, the relationship between the film thickness (nm) of the gate electrode formed of the Mo film and the Raman peaks (/cm) was investigated. FIG. 2 shows the measurement results. As described above, the deposition conditions (including the deposition temperature, which will be described later) except the film thickness were set to be the same values as those in the experiment in FIG. 1. It is seen from the figure that the Raman peaks increases as the film thickness of the gate electrode increases.

When the amount of strain in the polysilicon thin film resulting from the residual stress in the gate electrode is large, the Raman peaks shift to the low frequency side. Therefore, the thinner the film thickness of the gate electrode, the greater the amount of strain in the polysilicon thin film. As shown in FIG. 2, the relationship between the film thickness of the gate electrode and the Raman peak is not linear, but the Raman peak asymptotically approaches the value of about 517/cm as the film thickness increases. This means that when the film thickness of the gate electrode is large to some extent, the Raman peak will substantially stay at the level of about 517/cm even when the film thickness changes. Judging from FIG. 2, it is reasonable to assume that apparent decrease in Raman peak, that is, apparent increase in the amount of strain in the polysilicon thin film occurs where the film thickness of the gate electrode is about 500 nm or smaller.

An even larger amount of strain in the polysilicon thin film can be achieved only by reducing the film thickness of the gate electrode, for example, to 300 nm or smaller. From the viewpoint of eliminating effects (possibility of detachment of the gate electrode and the like) resulting from the reduction in film thickness of the gate electrode, the gate electrode is desirably 100 nm or thicker.

It is seen from FIG. 1 that the residual stress is 300 MPa or greater when the film thickness of the gate electrode made of Mo is 500 nm or smaller. It is considered that this numerical relationship applies to the above-mentioned other refractory metals as well as Mo. That is, in consideration of the effect resulting from the reduction in film thickness of the gate electrode, a large amount of strain can be imparted in the polysilicon thin film only by using a gate electrode having the film thickness of the gate electrode to be 100 nm to 500 nm, preferably from 100 nm to 300 nm, to ensure a residual stress of at least 300 MPa.

By forming the gate electrode under such deposition conditions, there is provided a TFT in which sufficient strain is reliably imparted in the polysilicon thin film so as to achieve high mobility without adding any extra step.

When residual stress of at least 300 MPa induced by the gate electrode is applied to the polysilicon thin film, the wave number of the Raman peak in Raman spectroscopy obtained from the polysilicon thin film shifts to the low frequency side by at least 0.2/cm relative to the wave number obtained before the formation of the gate electrode.

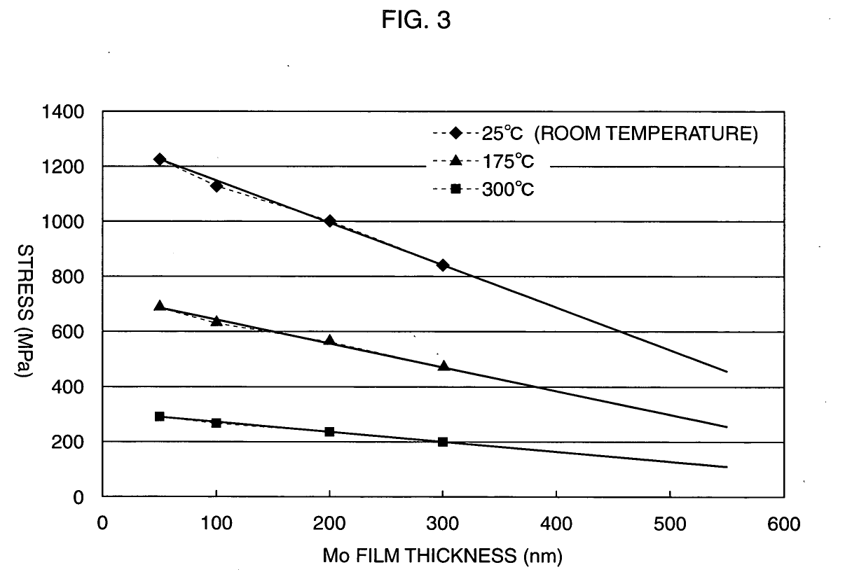

Although the primary parameter that determines the amount of strain imparted in the polysilicon thin film is the film thickness of the gate electrode, as a particularly influential parameter on the amount of strain other than the film thickness, the deposition temperature (ambient temperature in the chamber in this embodiment) for the metal film of the gate electrode is considered to be important. Then, by using the deposition temperature as a parameter as well as the film thickness of the gate electrode, the relationship between the film thickness (nm) of the Mo film deposited at a number of deposition temperatures and the residual stress (MPa) was investigated. FIG. 3 shows the measurement results. It is seen from the figure that the residual stress in the film of a predetermined film thickness tends to increase as the deposition temperature decreases. It should be noted that even when the deposition temperature changes, the residual stress keeps a substantially linear relationship with the film thickness of the Mo film, in which the former decreases as the latter increases.

From the above consideration, ensuring a residual stress of 300 MPa or greater in the gate electrode is considered to be the guideline to impart sufficient strain in the polysilicon thin film in order to achieve high mobility in a TFT. Therefore, the above purpose can be achieved by only adding the deposition temperature as the parameter for controlling the residual stress and using each deposition temperature disclosed in FIG. 3 as an experimental supportive evidence to adjust the deposition temperature in the range from 25° C. to 300° C. and the film thickness of the gate electrode in the range from 100 nm to 500 nm, preferably 100 nm to 300 nm so as to ensure a residual stress of 300 MPa or greater in the gate electrode.

By thus clearly defining two parameters, that is, the film thickness of the gate electrode and the deposition temperature and appropriately adjusting these parameters within the above ranges, the residual stress in the gate electrode can be reliably controlled in a further detailed manner at a desired value, which is 300 MPa or greater, according to various deposition environments.

Furthermore, in this case, in the area where the channel region of the polysilicon thin film will be formed, smaller sized crystal grains will increase grain boundaries, so that the residual stress induced by the gate electrode will be disadvantageously relaxed. Therefore, by increasing the crystal grain size in the area where the channel region of the polysilicon thin film will be formed, specifically by forming crystal grains of 400 nm or greater, sufficient strain in the polysilicon thin film is provided.

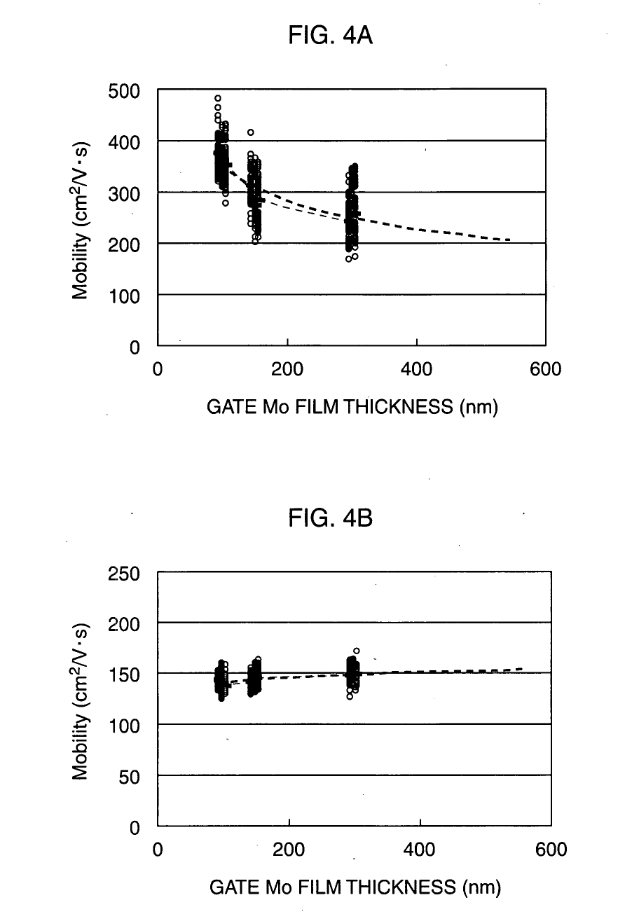

Then, the present inventor investigated the relationship between the film thickness (nm) of the gate electrode made of Mo and the mobility (cm²/V×s) for an n-channel TFT, which has an n-type source and drain, and a p-channel TFT, which has a p-type source and drain. FIGS. 4A and 4B show the measurement results. As shown in FIG. 4A, in the n-channel TFT, smaller film thickness of the gate electrode, specifically equal to or less than about 500 nm, improves the mobility. On the other hand, in the p-channel TFT shown in FIG. 4B, the mobility does not significantly depend on the film thickness of the gate electrode. In the p-channel TFT, since boron (B), which is an example used as a p-type impurity, is lighter than phosphorus (P), which is an example used as an n-type impurity, a thin gate electrode may disadvantageously allow implanted B ions to penetrate the gate electrode into the channel region.

Then, in consideration of the above circumstances, when the present invention is applied to a CMOS TFT formed of a p-channel TFT and an n-channel TFT, the gate electrode of the n-channel TFT, in which thinner film thickness of the gate electrode results in higher mobility, is formed such that the film thickness of the gate electrode of the n-channel TFT is smaller than that of the p-channel TFT. In this way, the performance of the n-channel TFT can be particularly improved without causing particular inconvenience to the p-channel TFT.

### Specific Embodiments to Which the Present Invention is Applied

Specific embodiments in which the present invention is applied to the configuration and manufacturing method of a polysilicon TFT will be described in detail with reference to the drawings. For convenience of explanation, the configuration and manufacturing method of the polysilicon TFT will be described together.

### First Embodiment

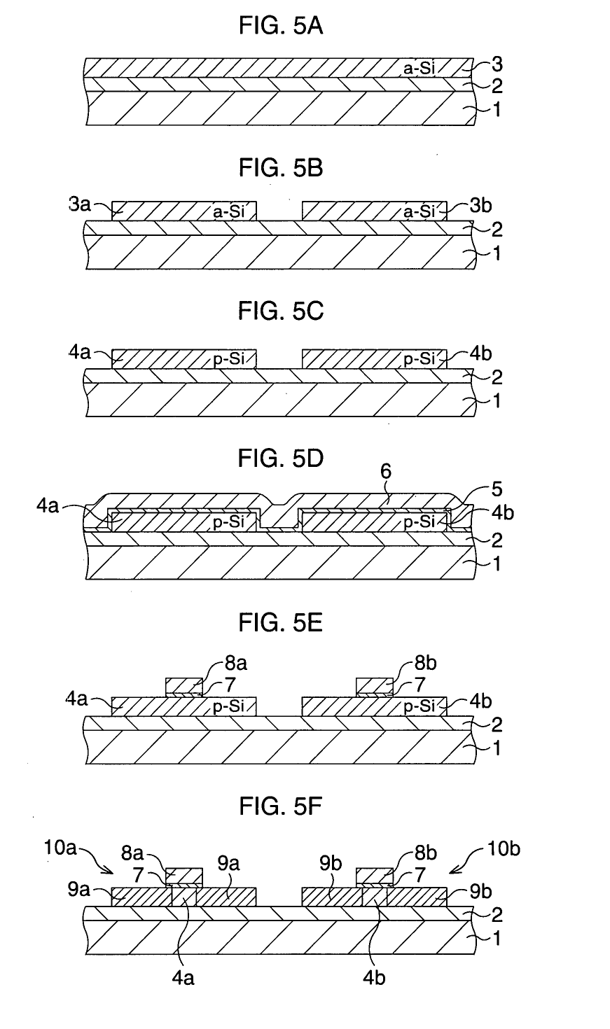

FIGS. 5A to 5F are schematic cross-sectional views showing a method for manufacturing the CMOS polysilicon TFT (hereinafter simply referred to as a CMOSTFT) according to a first embodiment. FIGS. 5A to 5F are arranged in the order of steps.

Firstly, as shown in FIG. 5A, plasma CVD is used to deposit an amorphous silicon thin film 3, for example, to a film thickness of about 65 nm on a transparent insulating substrate, such as a glass substrate 1, via a buffer layer 2 made of SiO₂ having a film thickness of about 400 nm. During deposition, by mixing B₂H₆ gas in the deposition chamber, for example, the amorphous silicon thin film 3 is doped with boron (B).

Then, as shown in FIG. 5B, the thus processed substrate undergoes a heat treatment at about 550° C. for about two hours in a nitrogen atmosphere to dehydrogenate the amorphous silicon layer 3. Thereafter, photolithography and dry etching is used to process the amorphous silicon thin film 3 into a pair of amorphous silicon thin films 3a and 3b having respective predetermined ribbon patterns.

Then, as shown in FIG. 5C, laser annealing is used to crystallize the amorphous silicon thin films 3a and 3b. Specifically, for example, an energy beam that continuously outputs energy with time, a Nd:YVO₄ laser in this embodiment, which is a semiconductor-pumped (LD-pumped) solid-state laser (DPSS laser), is used to apply the laser light to the amorphous silicon thin films 3a and 3b under the condition of an output of 6.5 W and a scan speed of 20 cm/second so as to crystallize and convert the amorphous silicon layers 3a and 3b into polysilicon thin films 4a and 4b. Thereafter, photolithography and dry etching is used to process the ribbon-patterned polysilicon thin films 4a and 4b into respective predetermined island patterns.

Then, as shown in FIG. 5D, plasma CVD is used to deposit a SiO₂ film 5 to a film thickness of about 30 nm across the surface such that the polysilicon thin films 4a and 4b are covered with the SiO₂ film 5. Thereafter, sputtering is used to deposit a refractory metal film, a Mo film 6 in this embodiment, which will be a gate electrode, on the SiO₂ film 5. In this step, the film thickness and the deposition temperature (ambient temperature in the sputtering chamber) are particularly used as primary parameters to control the formation of the Mo film 6 such that residual stress has a predetermined value of 300 MPa or greater and is oriented to increase the in-plane lattice constant. Specifically, the Mo film 6 is deposited to a film thickness of 100 nm to 500 nm (more preferably 100 nm to 300 nm), about 100 nm in this embodiment, under the condition of a pressure of 2×10⁻³ Torr, an input power (RF power) of 3.5 kW, a sputtering gas (Ar gas) flow rate of 20 sccm and a chamber temperature of 25° C. to 300° C., about 175° C. in this embodiment.

Then, as shown in FIG. 5E, photolithography and dry etching is used to process the Mo film 6 and the SiO₂ film 5 into the shape of an electrode on each of the polysilicon thin films 4a and 4b, so as to pattern gate electrodes 8a and 8b formed of the Mo film 6 with interposed gate insulating films 7 formed of the SiO₂ film 5. As described above, the gate electrodes 8a and 8b have been formed by particularly controlling the film thickness and the deposition temperature as the primary parameters, and consequently have a residual stress that is 300 MPa or greater, about 630 MPa in this embodiment, and oriented to increase the in-plane lattice constant. This residual stress applies tensile stress to the polysilicon thin films 4a and 4b at least in the channel regions therein, on which the gate electrodes 8a and 8b are formed, so that the in-plane lattice constant becomes larger than that will be achieved when no tensile stress is applied.

Then, as shown in FIG. 5F, a resist mask (not shown) is formed to cover the polysilicon thin film 4a side, and the gate electrode 8b is used as a mask to implant n-type impurity ions, phosphorus (P) ions in this embodiment, into the polysilicon thin film 4b on both sides of the gate electrode 8b so as to form an n-type source and drain 9b. The main configuration of an n-channel TFT 10b is thus completed, in which the gate electrode 8b is formed on the polysilicon thin film 4b via the gate insulating film 7 and the source and drain 9b are formed on the sides of the gate electrode 8b.

On the other hand, after ashing or the like is used to remove the resist mask, as shown in FIG. 5F, a resist mask (not shown) is formed to cover the polysilicon thin film 4b side, and the gate electrode 8a is used as a mask to implant p-type impurity ions, boron (B) ions in this embodiment, into the polysilicon thin film 4a on both sides of the gate electrode 8a so as to form a p-type source and drain 9a. The main configuration of a p-channel TFT 10a is thus completed, in which the gate electrode 8a is formed on the polysilicon thin film 4a via the gate insulating film 7 and the source and drain 9a are formed on the sides of the gate electrode 8a.

Thereafter, the CMOSTFT of this embodiment is completed, for example, by further forming an interlayer insulating film that covers the p-channel TFT 10a and the n-channel TFT 10b, and forming contact holes and various wiring layers that electrically connect the gate electrodes 8a and 8b to the sources and drains 9a and 9b, respectively.

As described above, according to this embodiment, desired strain can be easily and reliably imparted to the polysilicon thin films 4a and 4b to improve the mobility therein without adding an extra step of imparting the strain to the polysilicon thin films 4a and 4b, thereby achieving a high-performance CMOSTFT.

### Second Embodiment

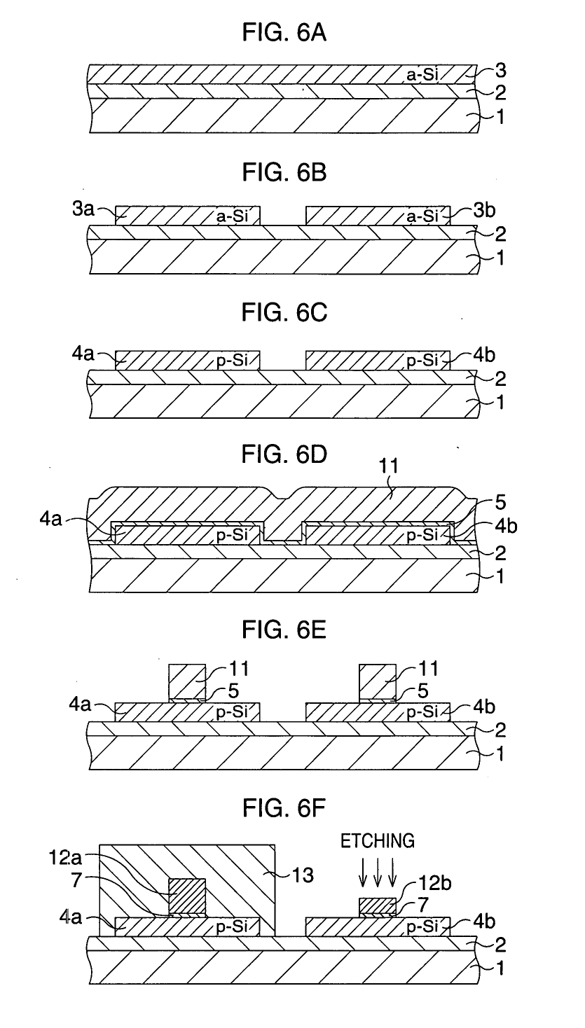

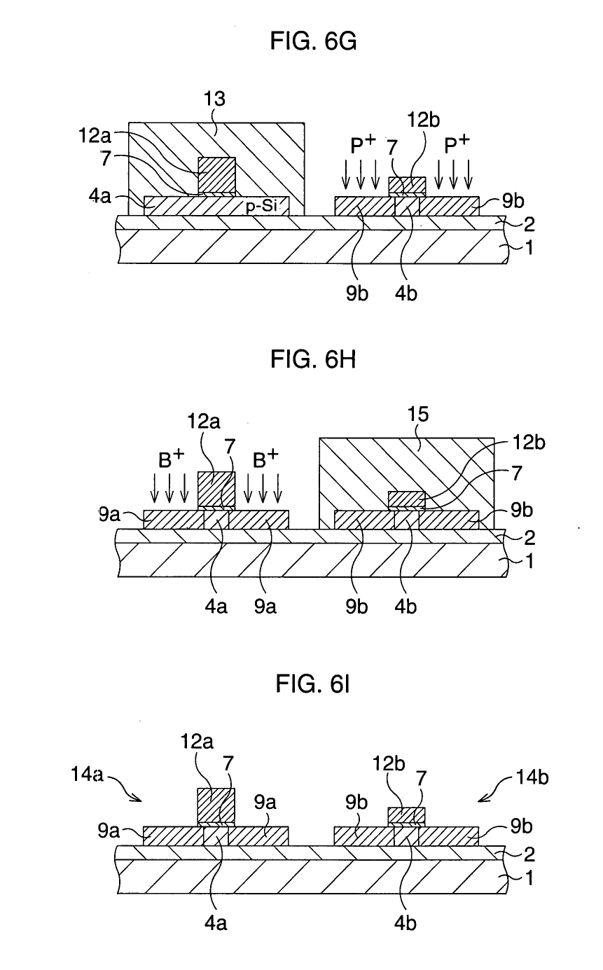

In this embodiment, there is disclosed a CMOSTFT configuration and manufacturing method substantially similar to those of the first embodiment except in that the film thickness of the gate electrode of the n-channel TFT is thinner than that of the p-channel TFT. FIGS. 6A to 6G are schematic cross-sectional views showing the method for manufacturing the CMOS polysilicon TFT (hereinafter simply referred to as a CMOSTFT) according to the second embodiment. FIGS. 6A to 6G are arranged in the order of steps. Component members and the like common to those of the first embodiment have the same reference characters.

Firstly, as shown in FIG. 6A, plasma CVD is used to deposit an amorphous silicon thin film 3, for example, to a film thickness of about 65 nm on a transparent insulating substrate, such as a glass substrate 1, via a buffer layer 2 made of SiO₂ having a film thickness of about 400 nm. During deposition, by mixing B₂H₆ gas in the deposition chamber, for example, the amorphous silicon thin film 3 is doped with boron (B).

Then, as shown in FIG. 6B, the thus processed substrate undergoes a heat treatment at about 550° C. for about two hours in a nitrogen atmosphere to dehydrogenate the amorphous silicon layer 3. Thereafter, photolithography and dry etching is used to process the amorphous silicon thin film 3 into a pair of amorphous silicon thin films 3a and 3b having respective predetermined ribbon patterns.

Then, as shown in FIG. 6C, laser annealing is used to crystallize the amorphous silicon thin films 3a and 3b. Specifically, for example, an energy beam that continuously outputs energy with time, a Nd:YVO₄ laser in this embodiment, which is a semiconductor-pumped (LD-pumped) solid-state laser (DPSS laser), is used to apply the laser light to the amorphous silicon thin films 3a and 3b under the condition of an output of 6.5 W and a scan speed of 20 cm/second so as to crystallize and convert the amorphous silicon layers 3a and 3b into polysilicon thin films 4a and 4b. Thereafter, photolithography and dry etching is used to process the ribbon-patterned polysilicon thin films 4a and 4b into respective predetermined island patterns.

Then, as shown in FIG. 6D, plasma CVD is used to deposit a SiO₂ film 5 to a film thickness of about 30 nm across the surface such that the polysilicon thin films 4a and 4b are covered with the SiO₂ film 5. Thereafter, sputtering is used to deposit a refractory metal film, a Mo film 11 in this embodiment, which will be a gate electrode, on the SiO₂ film 5. In this step, the film thickness and the deposition temperature (ambient temperature in the sputtering chamber) are particularly used as primary parameters to control the formation of the Mo film 11 such that residual stress has a predetermined value of 300 MPa or greater and is oriented to increase the in-plane lattice constant. Specifically, the Mo film 11 is deposited to a film thickness of 100 nm to 500 nm (more preferably 100 nm to 300 nm), about 300 nm in this embodiment, under the condition of a pressure of 2×10⁻³ Torr, an input power (RF power) of 3.5 kW, a sputtering gas (Ar gas) flow rate of 20 sccm and a chamber temperature of 25° C. to 300° C., about 175° C. in this embodiment.

Then, as shown in FIG. 6E, photolithography and dry etching is used to process the Mo film 11 and the SiO₂ film 5 into the shape of an electrode on each of the polysilicon thin films 4a and 4b.

Then, as shown in FIG. 6F, a resist mask 13 is formed to cover only the polysilicon thin film 4a side on the left in the figure, and only the Mo film 11 on the polysilicon thin film 4b is dry etched to reduce the film thickness of the Mo film 11 to about 100 nm. At this point, a gate electrode 12a made of Mo and having a film thickness of about 300 nm is formed on the polysilicon thin film 4a via the gate insulting film 7, while a gate electrode 12b made of Mo and having a film thickness of about 100 nm is formed on the polysilicon thin film 4b via the gate insulting film 7.

As described above, the gate electrodes 12a and 12b have been formed by particularly controlling the film thickness and the deposition temperature as the primary parameters, and consequently have a residual stress that is 300 MPa or greater, about 470 MPa in the gate electrode 12a and about 630 MPa in the gate electrode 12b due to the effect of the reduction in film thickness in this embodiment, and oriented to increase the in-plane lattice constant. This residual stress applies tensile stress to the polysilicon thin films 4a and 4b at least in the channel regions therein, on which the gate electrodes 12a and 12b are formed, so that the in-plane lattice constant becomes larger than that will be achieved when no tensile stress is applied.

Then, as shown in FIG. 6G, the resist mask 13 is used as it is as a mask against ion implantation, and the gate electrode 12b is used as a mask on the polysilicon thin film 4b side to implant n-type impurity ions, phosphorus (P) ions in this embodiment, into the polysilicon thin film 4b on both sides of the gate electrode 12b so as to form an n-type source and drain 9b. The main configuration of an n-channel TFT 14b is thus completed, in which the gate electrode 12b is formed on the polysilicon thin film 4b via the gate insulating film 7 and the source and drain 9b are formed on the sides of the gate electrode 12b.

On the other hand, after ashing or the like is used to remove the resist mask 13, as shown in FIG. 6H, a resist mask 15 is formed to cover the polysilicon thin film 4b side, and the gate electrode 12a is used as a mask on the polysilicon thin film 4a side to implant p-type impurity ions, boron (B) ions in this embodiment, into the polysilicon thin film 4a on both sides of the gate electrode 12a so as to form a p-type source and drain 9a. Then, by using ashing or the like to remove the resist mask 15, the main configuration of a p-channel TFT 14a is completed, in which the gate electrode 12a is formed on the polysilicon thin film 4a via the gate insulating film 7 and the source and drain 9a are formed on the sides of the gate electrode 12a, as shown in FIG. 6I.

Thereafter, the CMOSTFT of this embodiment is completed, for example, by further forming an interlayer insulating film that covers the p-channel TFT 14a and the n-channel TFT 14b, and forming contact holes and various wiring layers that electrically connect the gate electrodes 12a and 12b to the sources and drains 9a and 9b, respectively.

As described above, according to this embodiment, desired strain can be easily and reliably imparted to the polysilicon thin films 4a and 4b to improve the mobility particularly in the n-channel TFT 14b without adding an extra step of imparting the strain to the polysilicon thin films 4a and 4b, thereby achieving a high-performance CMOSTFT.

### Example of Variation

An example of the variation of the second embodiment will be described below.

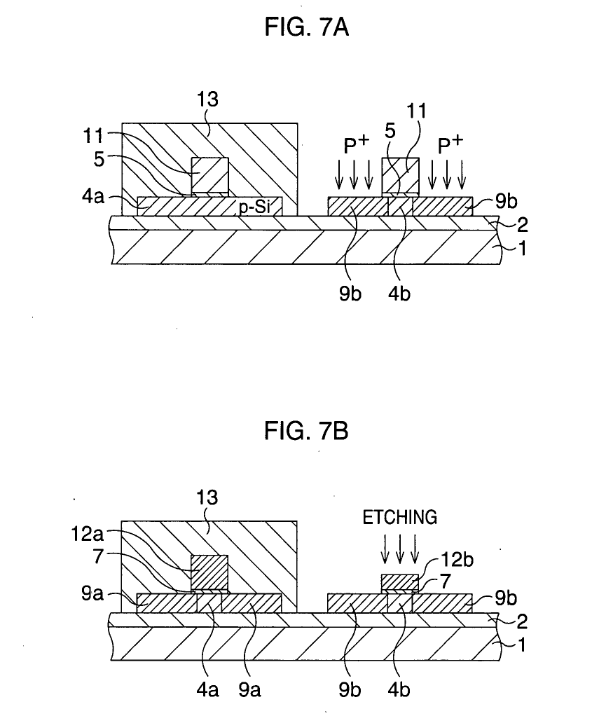

FIGS. 7A and 7B are schematic cross-sectional views showing the primary steps of this example of the variation.

Firstly, steps similar to those shown in FIGS. 6A to 6E are carried out.

Then, as shown in FIG. 7A, the resist mask 13 is formed to cover only the polysilicon thin film 4a side on the left in the figure, and the Mo film 11 is used as a mask on the polysilicon thin film 4b side to implant n-type impurity ions, phosphorus (P) ions in this example, into the polysilicon thin film 4b on both sides of the Mo film 11 so as to form the n-type source and drain 9b.

Then, as shown in FIG. 7B, the resist mask 13 is used as it is as a mask against etching, and only the Mo film 11 on the polysilicon thin film 4b is dry etched to reduce the film thickness of the Mo film 11 to about 100 nm. At this point, the gate electrode 12a made of Mo and having a film thickness of about 300 nm is formed on the polysilicon thin film 4a via the gate insulting film 7, while the gate electrode 12b made of Mo and having a film thickness of about 100 nm is formed on the polysilicon thin film 4b via the gate insulting film 7.

After carrying out the steps similar to those shown in FIGS. 6H and 6I, the CMOSTFT of this example of the variation is completed, for example, by further forming an interlayer insulating film that covers the p-channel TFT 14a and the n-channel TFT 14b, and forming contact holes and various wiring layers that electrically connect the gate electrodes 12a and 12b to the sources and drains 9a and 9b, respectively.

As described above, according to this variation, desired strain can be easily and reliably imparted to the polysilicon thin films 4a and 4b to improve the mobility particularly in the n-channel TFT 14b without adding an extra step of imparting the strain to the polysilicon thin films 4a and 4b, thereby achieving a high-performance CMOSTFT.

Furthermore, in this example of the variation, before processing the Mo film 11 into the gate electrode 12b on the n-channel TFT 14b side, the thick (about 300 nm in this example) Mo film 11 is used as the mask to implant P ions. Although the n-channel TFT will not suffer the impurity penetration problem during ion implantation as noticeably as that in the p-channel TFT, use of the gate electrode 12b as thin as about 100 nm as the mask may not eliminate the impurity penetration problem. Therefore, as in this example of the variation, by using the still thick Mo film 11 as the mask to implant the ions, the n-channel TFT 14b can be formed without concern about impurity penetration, while the number of steps is not increased or the steps do not become complicated.

### Third Embodiment

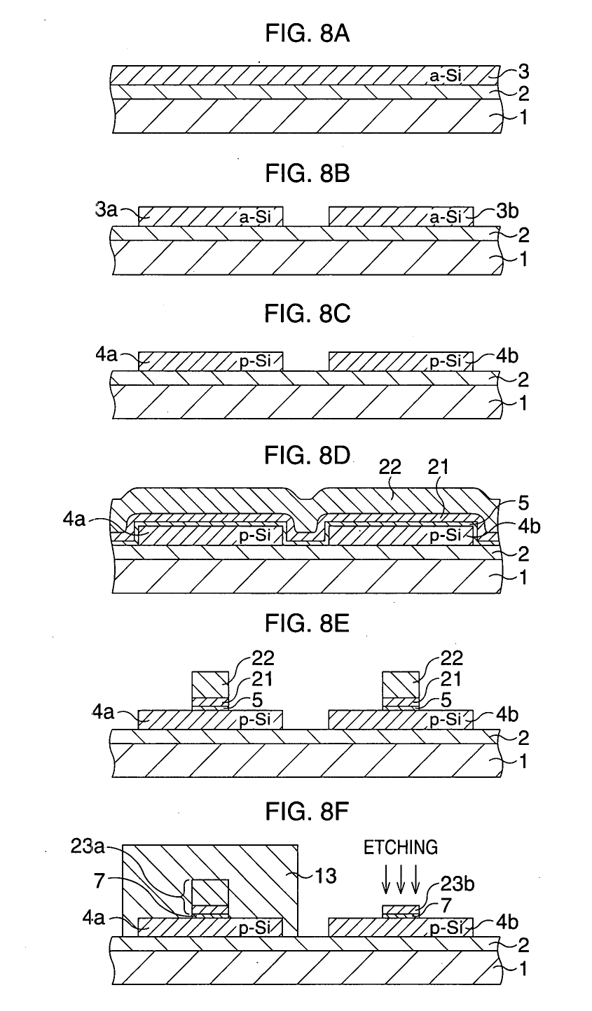

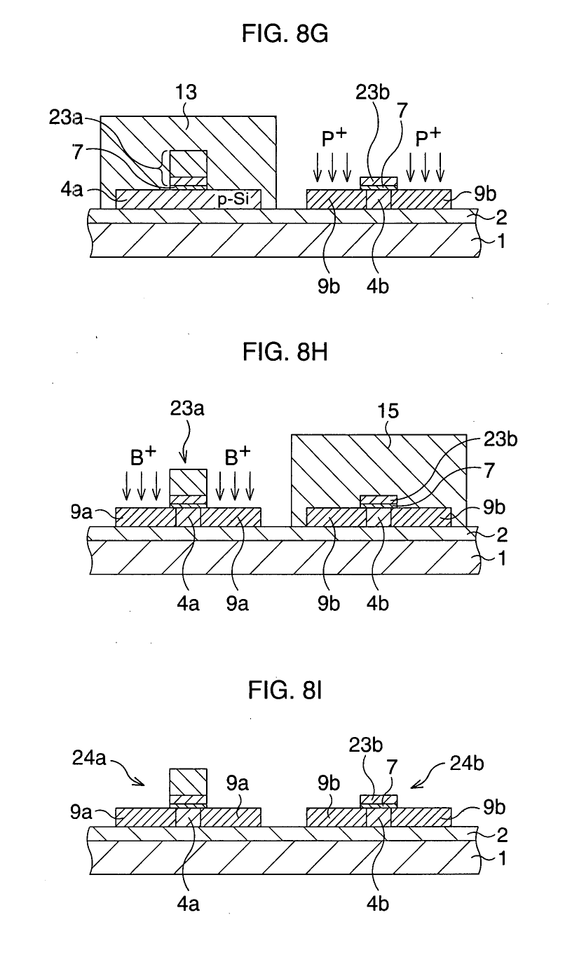

In this embodiment, there is disclosed a CMOSTFT configuration and manufacturing method substantially similar to those of the second embodiment except in that a two-layer gate electrode of the p-channel TFT is formed in order to make the film thickness of the gate electrode of the n-channel TFT smaller than that of the p-channel TFT. FIGS. 8A to 8G are schematic cross-sectional views showing the method for manufacturing the CMOS polysilicon TFT (hereinafter simply referred to as a CMOSTFT) according to the third embodiment. FIGS. 8A to 8G are arranged in the order of steps. Component members and the like common to those of the second embodiment have the same reference characters.

Firstly, as shown in FIG. 8A, plasma CVD is used to deposit an amorphous silicon thin film 3, for example, to a film thickness of about 65 nm on a transparent insulating substrate, such as a glass substrate 1, via a buffer layer 2 made of SiO₂ having a film thickness of about 400 nm. During deposition, by mixing B₂H₆ gas in the deposition chamber, for example, the amorphous silicon thin film 3 is doped with boron (B).

Then, as shown in FIG. 8B, the thus processed substrate undergoes a heat treatment at about 550° C. for about two hours in a nitrogen atmosphere to dehydrogenate the amorphous silicon layer 3. Thereafter, photolithography and dry etching is used to process the amorphous silicon thin film 3 into a pair of amorphous silicon thin films 3a and 3b having respective predetermined ribbon patterns.

Then, as shown in FIG. 8C, laser annealing is used to crystallize the amorphous silicon thin films 3a and 3b. Specifically, for example, an energy beam that continuously outputs energy with time, a Nd:YVO₄ laser in this embodiment, which is a semiconductor-pumped (LD-pumped) solid-state laser (DPSS laser), is used to apply the laser light to the amorphous silicon thin films 3a and 3b under the condition of an output of 6.5 W and a scan speed of 20 cm/second so as to crystallize and convert the amorphous silicon layers 3a and 3b into polysilicon thin films 4a and 4b. Thereafter, photolithography and dry etching is used to process the ribbon-patterned polysilicon thin films 4a and 4b into respective predetermined island patterns.

Then, as shown in FIG. 8D, plasma CVD is used to deposit a SiO₂ film 5 to a film thickness of about 30 nm across the surface such that the polysilicon thin films 4a and 4b are covered with the SiO₂ film 5. Thereafter, sputtering is used to deposit in a laminated manner a refractory metal film, a Mo film 21 and a Ti film 22 in this embodiment, which will be a gate electrode, on the SiO₂ film 5. In this step, the film thickness and the deposition temperature (ambient temperature in the sputtering chamber) are particularly used as primary parameters to control the formation of the Mo film 21 and the Ti film 22 such that residual stress has a predetermined value of 300 MPa or greater and is oriented to increase the in-plane lattice constant.

Specifically, the Mo film 21 is deposited to about 100 nm in this embodiment such that the laminated film thickness of the Mo film 21 and the Ti film 22 is 100 nm to 500 nm (more preferably 100 nm to 300 nm) under the condition of a pressure of 2×10⁻³ Torr, an input power (RF power) of 3.5 kW, a sputtering gas (Ar gas) flow rate of 20 sccm and a chamber temperature of 25° C. to 300° C., about 175° C. in this embodiment.

On the other hand, the Ti film 22 is deposited to about 200 nm in this embodiment such that the laminated film thickness of the Mo film 21 and the Ti film 22 is 100 nm to 500 nm (more preferably 100 nm to 300 nm) under the condition of a pressure of 2×10⁻³ Torr, an input power (DC power) of 2.0 kW, a sputtering gas (Ar gas) flow rate of 125 sccm and a chamber temperature of 25° C. to 300° C., about 125° C. in this embodiment.

Then, as shown in FIG. 8E, photolithography and dry etching is used to process the Ti film 22, the Mo film 21 and the SiO₂ film 5 into the shape of an electrode on each of the polysilicon thin films 4a and 4b.

Then, as shown in FIG. 8F, a resist mask 13 is formed to cover only the polysilicon thin film 4a side on the left in the figure, and the Mo film 21 on the polysilicon thin film 4b is used as an etching stopper to dry etch only the Ti film 22, leaving the Mo film 21. In this case, since the difference in etching speed between Mo and Ti is utilized and the Mo film 21 is used as the etching stopper, only the Mo film 21 is left and an intended film thickness (about 100 nm in this embodiment) can be more easily achieved, for example, compared to the case where the film thickness is controlled by dry etching a single layer refractory metal film.

At this point, a gate electrode 23a made of laminated Mo and Ti and having a film thickness of about 300 nm is formed on the polysilicon thin film 4a via the gate insulting film 7, while a gate electrode 23b made of Mo and having a film thickness of about 100 nm is formed on the polysilicon thin film 4b via the gate insulting film 7.

As described above, the gate electrodes 23a and 23b have been formed by particularly controlling the film thickness and the deposition temperature as the primary parameters, and consequently have a residual stress of 300 MPa or greater, about 630 MPa particularly in the gate electrode 23b due to the effect of the reduction in film thickness in this embodiment, and oriented to increase the in-plane lattice constant. This residual stress applies tensile stress to the polysilicon thin films 4a and 4b at least in the channel regions therein, on which the gate electrodes 23a and 23b are formed, so that the in-plane lattice constant in the polysilicon thin films 4a arid 4b becomes larger than that will be achieved when no tensile stress is applied.

Then, as shown in FIG. 8G, the resist mask 13 is used as it is as a mask against ion implantation, and the gate electrode 23b is used as a mask on the polysilicon thin film 4b side to implant n-type impurity ions, phosphorus (P) ions in this embodiment, into the polysilicon thin film 4b on both sides of the gate electrode 23b so as to form an n-type source and drain 9b. The main configuration of an n-channel TFT 24b is thus completed, in which the gate electrode 23b is formed on the polysilicon thin film 4b via the gate insulating film 7 and the source and drain 9b are formed on the sides of the gate electrode 23b .

On the other hand, after ashing or the like is used to remove the resist mask 13, as shown in FIG. 8H, a resist mask 15 is formed to cover the polysilicon thin film 4b side, and the gate electrode 23a is used as a mask on the polysilicon thin film 4a side to implant p-type impurity ions, boron (B) ions in this embodiment, into the polysilicon thin film 4a on both sides of the gate electrode 23a so as to form a p-type source and drain 9a. Then, by using ashing or the like to remove the resist mask 15, the main configuration of a p-channel TFT 24a is completed, in which the gate electrode 23a is formed on the polysilicon thin film 4a via the gate insulating film 7 and the source and drain 9a are formed on the sides of the gate electrode 23a, as shown in FIG. 8I.

Thereafter, the CMOSTFT of this embodiment is completed, for example, by further forming an interlayer insulating film that covers the p-channel TFT 24a and the n-channel TFT 24b, and forming contact holes and various wiring layers that electrically connect the gate electrodes 23a and 23b to the sources and drains 9a and 9b, respectively.

As described above, according to this embodiment, desired strain can be easily and reliably imparted to the polysilicon thin films 4a and 4b to improve the mobility particularly in the n-channel TFT 24b without adding an extra step of imparting the strain to the polysilicon thin films 4a and 4b, thereby achieving a high-performance CMOSTFT.

### Example of Variation

An example of the variation of the third embodiment will be described below.

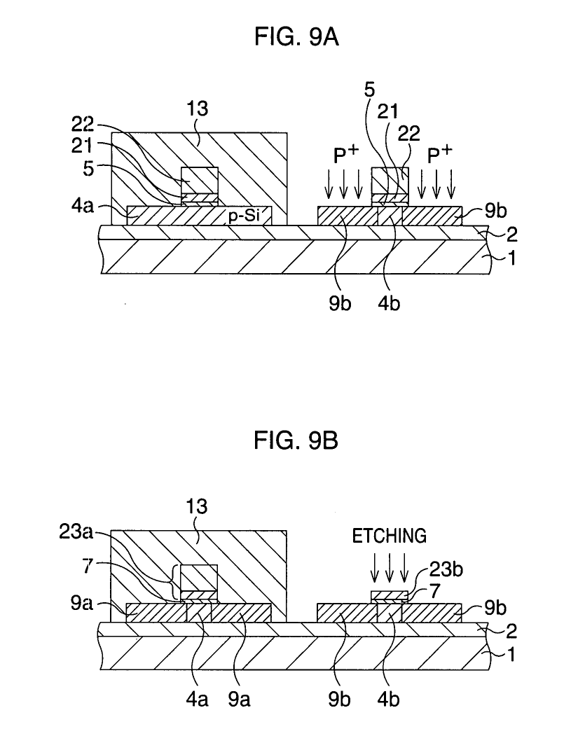

FIGS. 9A and 9B are schematic cross-sectional views showing the primary steps of this example of the variation.

Firstly, steps similar to those shown in FIGS. 8A to 8E are carried out.

Then, as shown in FIG. 9A, the resist mask 13 is formed to cover only the polysilicon thin film 4a side on the left in the figure, and the Ti film 22 and the Mo film 21 are used as a mask on the polysilicon thin film 4b side to implant n-type impurity ions, phosphorus (P) ions in this example, into the polysilicon thin film 4b on both sides of the Mo film 11 so as to form the n-type source and drain 9b.

Then, as shown in FIG. 9B, the resist mask 13 is used as it is as a mask against etching, and the Mo film 21 on the polysilicon thin film 4b is used as an etching stopper to dry etch only the Ti film 22, leaving the Mo film 21. In this case, since the difference in etching speed between Mo and Ti is utilized and the Mo film 21 is used as the etching stopper, only the Mo film 21 is left and an intended film thickness (about 100 nm in this embodiment) can be more easily achieved, for example, compared to the case where the film thickness is controlled by dry etching a single layer refractory metal film.

At this point, the gate electrode 23a made of laminated Mo and Ti and having a film thickness of about 300 nm is formed on the polysilicon thin film 4a via the gate insulting film 7, while the gate electrode 23b made of Mo and having a film thickness of about 100 nm is formed on the polysilicon thin film 4b via the gate insulting film 7.

After carrying out the steps similar to those shown in FIGS. 6H and 6I, the CMOSTFT of this example of the variation is completed, for example, by further forming an interlayer insulating film that covers the p-channel TFT 24a and the n-channel TFT 24b, and forming contact holes and various wiring layers that electrically connect the gate electrodes 23a and 23b to the sources and drains 9a and 9b, respectively.

As described above, according to this variation, desired strain can be easily and reliably imparted to the polysilicon thin films 4a and 4b to improve the mobility particularly in the n-channel TFT 24b without adding an extra step of imparting the strain to the polysilicon thin films 4a and 4b, thereby achieving a high-performance CMOSTFT.

Furthermore, in this example of the variation, before etching away the Ti film 22 to form the gate electrode 23b on the n-channel TFT 24b side, the thick (about 300 nm in this example) Ti film 22 and Mo film 21 are used as the mask to implant P ions. Although the n-channel TFT will not suffer the impurity penetration problem during ion implantation as noticeably as that in the p-channel TFT, use of the gate electrode 23b as thin as about 100 nm as the mask may not eliminate the impurity penetration problem. Therefore, as in this example of the variation, by using the still thick Ti film 22 and Mo film 21 as the mask to implant the ions, the n-channel TFT 24b can be formed without concern about impurity penetration, while the number of steps is not increased or the steps do not become complicated.

The present invention is not limited to the first to third embodiments or the examples of the variation thereof. For example, in the second and third embodiments and the examples of the variation thereof, the film thickness of the gate electrode of the p-channel TFT may be formed to be smaller than the film thickness of the gate electrode of the n-channel TFT (that is, in this case, the illustration will be reversed in FIGS. 6A to 6I, 7A, 7B, 8A to 8I, 9A and 9B). In particular, when the film thickness of the gate electrode of the p-channel TFT is formed to be smaller than the film thickness of the gate electrode of the n-channel TFT in the examples of the variation shown in FIGS. 7A, 7B, 9A and 9B, the impurity penetration problem during ion implantation will be serious in the p-channel TFT. In this case, by performing the ion implantation while the thick refractory metal film (the Mo film, or the Mo film and the Ti film) formed into the electrode shape still remains, the p-channel TFT can be formed without concern about impurity penetration, while the number of steps is not increased or the steps do not become complicated.

### INDUSTRIAL APPLICABILITY

According to the present invention, there is provided a reliable thin film semiconductor device in which desired strain can be easily and reliably imparted to a semiconductor thin film to improve the mobility therein without adding an extra step of imparting the strain to the semiconductor thin film.

What is claimed is:

1. A thin film semiconductor device comprising:
an insulating substrate;
a semiconductor thin film patterned on the insulating substrate; and
a gate electrode patterned on the semiconductor thin film via a gate insulating film,
wherein the gate electrode has a film thickness ranging from 100 nm to 500 nm and has residual stress of 300 MPa or greater oriented to increase the in-plane lattice constant.

2. The thin film semiconductor device according to claim 1, wherein the film thickness of the gate electrode ranges from 100 nm to 300 nm.

3. The thin film semiconductor device according to claim 2, wherein the semiconductor thin film is a silicon film whose crystal grain size is 400 nm or greater at least in the channel region of the silicon film.

4. The thin film semiconductor device according to claim 2, wherein the semiconductor thin film is a silicon film and the wave number of the Raman peak in Raman scattering is 517/cm or smaller at least in the channel region of the silicon film.

5. The thin film semiconductor device according to claim 2, wherein the semiconductor thin film is a silicon film and the wave number of the Raman peak in Raman scattering at least in the channel region of the silicon film shifts to the low frequency side by at least 0.2/cm relative to the wave number obtained before the formation of the gate electrode.

6. The thin film semiconductor device according to claim 2, wherein the gate electrode includes one metal selected from a group of metals, Mo, W, Ti, Nb, Re and Ru, an alloy of a plurality of metals selected from the group of metals or a laminated structure of a plurality of metals selected from the group of metals.

7. The thin film semiconductor device according to claim 2, wherein the semiconductor thin film comprises a pair of the semiconductor thin films, each of which provided with the gate electrode thereon via the gate insulating film, and
one of the gate electrodes is formed to be thinner than the other one of the gate electrodes.

8. The thin film semiconductor device according to claim 7, wherein the number of layers of the other one of the gate electrodes is greater than that of the one of the gate electrodes.

9. A method for manufacturing a thin film semiconductor device comprising the steps of:
pattering a semiconductor thin film on an insulating substrate; and
patterning a gate electrode on the semiconductor thin film via a gate insulating film,
wherein the gate electrode is formed such that the film thickness thereof is adjusted to be a value ranging from 100 nm to 500 nm so as to create residual stress of 300 MPa or greater oriented to increase the in-plane lattice constant, and the residual stress induces tensile stress in the semiconductor thin film, so that the in-plane lattice constant thereof is controlled to be larger than that will be achieved when the tensile stress is not applied.

10. The method for manufacturing a thin film semiconductor device according to claim 9, wherein the gate electrode is formed such that the film thickness thereof is adjusted to be a value ranging from 100 nm to 300 nm so as to create residual stress of 300 MPa or greater oriented to increase the in-plane lattice constant.

11. The method for manufacturing a thin film semiconductor device according to claim 9, wherein the gate electrode is formed such that the film thickness thereof is adjusted to be a value ranging from 100 nm to 300 nm and the ambient temperature during deposition is adjusted to be a value ranging from 25° C. to 300° C. so as to create residual stress of 300 MPa or greater oriented to increase the in-plane lattice constant.

12. The method for manufacturing a thin film semiconductor device according to claim 11, wherein after the semiconductor thin film in an amorphous state is formed on the insulating substrate, laser light is applied to the semiconductor thin film to crystallize the semiconductor thin film.

13. The method for manufacturing a thin film semiconductor device according to claim 11, wherein the semiconductor thin film is a silicon film and the crystal grain size at least in the channel region of the silicon film is 400 nm or greater.

14. The method for manufacturing a thin film semiconductor device according to claim 11, wherein the gate electrode is made of material including one metal selected from a group of metals, Mo, W, Ti, Nb, Re and Ru, an alloy of a plurality of metals selected from the group of metals or a laminated structure of a plurality of metals selected from the group of metals.

15. The method for manufacturing a thin film semiconductor device according to claim 11 wherein a pair of the semiconductor thin films are simultaneously formed on the insulating substrate, and
the gate electrode is formed on each of the semiconductor thin films via the gate insulating film such that one of the gate electrodes is thinner than the other one of the gate electrodes.

16. The method for manufacturing a thin film semiconductor device according to claim 15, wherein after the gate electrodes are simultaneously formed to the film thickness of the other one of the gate electrodes, only the one of the gate electrodes is etched to be thinner.

17. The method for manufacturing a thin film semiconductor device according to claim 15, wherein after the gate electrodes are simultaneously formed to the film thickness of the other one of the gate electrodes and an impurity is introduced into the semiconductor thin film on which the one of the gate electrodes is formed, only the one of the gate electrodes is etched to be thinner.

18. The method for manufacturing a thin film semiconductor device according to claim 15, wherein after a plurality of metal layers are laminated to simultaneously form the gate electrodes to the film thickness of the other one of the gate electrodes, at least the top metal layer is etched only for the one of the gate electrodes to reduce the thickness thereof.

19. The method for manufacturing a thin film semiconductor device according to claim 15, wherein after a plurality of metal layers are laminated to simultaneously form the gate electrodes to the film thickness of the other one of the gate electrodes and an impurity is introduced into the semiconductor thin film on which the one of the gate electrodes is formed, at least the top metal layer is etched only for the one of the gate electrodes to reduce the thickness thereof.
